(19) United States
(12) Patent Application Publication
(10) Pub. No.: US 2004/0212405 A1
(43) Pub. Date: Oct. 28, 2004

(54) Pull up for high speed structures

(76) Inventors: Alexander Roger Deas, Edinburgh (GB); Igor Anatolievich Abrosimov, St. Petersburg (RU); Sergey Mikhailovich Dedov, St. Petersburg (RU)

Correspondence Address: NILOVA, Maria, 58, Moika Embankment, Office 501, St. Petersburg, 190000, RU

(21) Appl. No.: 10/853,123

(22) Filed: May 26, 2004

Related U.S. Application Data
(63) Continuation-in-part of application No. PCT/RU03/00242, filed on May 28, 2003.
(60) Provisional application No. 60/383,131, filed on May 28, 2002.

(51) Int. Cl. H03K 5/22

(52) U.S. Cl. 327/108

(57) ABSTRACT

The present invention relates to a pull-up structure with variable strength, which combines a resistor network with N type MOS transistors. According to the invention, the pull up structure comprises an N-channel type MOSFET with a resistor in parallel. Alternatively, a resistor is connected between the terminal of the pull up and a voltage supply, or between the source of the N Type MOSFET and the terminal of the pull up, i.e. in series with the gate. This allows the pull up to be varied to compensate for process and temperature variations around a predefined pull-up strength, and at the same time provides low parasitic capacitance and a good dynamic response of the pull-up structure.

### CROSS-REFERENCE TO RELATED APPLICATIONS

This application is a Continuation-in-Part of a PCT application PCT/RU03/00242 filed on 28 May 2003 claiming priority of U.S. provisional application 60/383,131 filed on 28 May 2002.

### TECHNICAL FIELD

The present invention relates to pull ups for high speed structures, particularly for differential current mode structures, having the benefit of reduced parasitic capacitance and improved performance on the structure switching.

### BACKGROUND OF THE INVENTION

Current mode logic, particularly differential current mode logic, is used to build fast circuits from MOS devices. The differential logic has benefits of reduced EMI, reduced ground bounce and less noisy switching currents. The current mode allows the logic to work at higher frequencies by maintaining portions of the circuit in linear modes. Other high speed single ended logic using open drain gates also have a need for effective pull ups.

Differential logic uses voltage or current references to control the operating point of the structure. FIG. 1 shows a simple differential stage which can be used as an inverter or a non-inverting buffer depending on the connection polarity of the outputs to the next differential stage. The key features of this differential stage is a current source, 1, implemented in the simplest case using a transistor with a fixed voltage on the gate from a voltage source, 2, the two transistors, 3 and 4, forming the logic function of the inverter/buffer, with a pull up structure 5, 6 which can be in the simplest case two resistors. These differential gates are well known in the prior art and date their use back for many decades.

The devices of the above type send signals on an open-drain signal line by controlling a transistor coupled between the open drain signal line and ground. Typically the transistor, which is used as a switch, is an N-channel MOSFET, but other types of transistors are also suitable for this purpose. In addition, the transistor may be internal to the device, or the device may have a terminal for controlling an external transistor.

When the device causes the transistor to be ON, the signal line is coupled to ground, causing its voltage to be pulled down to a LOW state or level, e.g., less than about 0.4 volts. Conversely, when all devices cause their corresponding driver transistors to be OFF, the signal line is biased to a HIGH state, e.g., 5 volts, by pull-up circuitry connected between the signal line and a power supply rail.

The speed at which signals may be transmitted on an open-drain signal line is dependent on how rapidly the signal line can be cycled between LOW and HIGH levels. Because of parasitic capacitance associated with the signal line, the rate at which it may be switched is determined by how rapidly the parasitic capacitance may be charged and discharged. Other factors being equal, an increase in parasitic capacitance slows the charge and discharge rates, and lowers the maximum signaling rate. Therefore, many open-drain based interconnection standards specify a maximum signal line capacitance, typically a few hundred picofarads, to ensure adequate performance.

Another factor determining the rate at which the parasitic capacitance is charged and discharged is the resistance in the charge and discharge current paths. Since the resistance of an output transistor is typically very small when the transistor is ON, the parasitic capacitance may be discharged very rapidly, and the transition from HIGH to LOW occurs quickly. However, the parasitic capacitance is charged by pull-up current provided by some form of pull-up circuitry.

In a typical application employing an open-drain signal line, the pull-up circuitry is simply a pull-up resistor coupled between the signal line and a positive supply rail. The pull up structures of the above type are widely used. U.S. Pat. No. 5,760,447 describes a semiconductor device employing a CMOSFET, including n-channel and p-channel MOSFETs. A terminal of the device is connected to a node coupling the drains of the MOSFETs, and a pull-up or pull-down resistor composed of two serially-connected resistances is connected between the terminal and a power source potential.

Because the resistance of a pull-up resistor is typically much larger than the ON resistance of a driver transistor, the rate at which the parasitic capacitance may be charged is much slower than the rate at which it may be discharged. The signal rise time is, therefore, much slower than the signal fall time.

Furthermore, resistors are too variable when fabricated on integrated circuits due to their variation in value with process parameters and temperature. This variation results in the two sides of the differential stage having different current levels, negating the main purpose of differential structures. Due to these process variations, pull up structures are normally implemented as a transistor with variable conductance to cover variations in their environment and fabrication. FIG. 2 shows various arrangements of these pull up transistors known in the prior art (FIG. 2a and FIG. 2b), which are P-type MOSFETs and a structure using an N type MOSFET in FIG. 2c.

As for p-channel MOSFET transistors used in some known pull up circuits, such as disclosed in JP 5041494, it shall be noted that they have significant drawbacks, the most important being parasitic capacitance seriously deteriorating operation speed of the transistors and are not suitable for the purposes of the present invention.

One technique for increasing the speed of operation is to use a smaller valued pull-up resistor. The N type MOSFET has the advantage of greater charge mobility and due to this, a smaller structure can be implemented for the same current, and hence, a lower parasitic capacitance can be charged more quickly when all driver transistors are OFF. This reduction in parasitic capacitance is a primary benefit for high speed operation. However, reducing pull-up resistance may have adverse effects on circuit operation. For example, reducing the value of the pull-up resistor increases current flow from Vcc to ground when a driver transistor is ON. This increased current represents wasted electrical power, which may be an important consideration in low power applications such as battery powered devices. The increased current also increases the voltage drop across the driver transistor, thereby raising the signal line voltage and reducing the noise margin associated with a LOW signal line level.

One type of MOSFET transistors commonly used in the prior art is n-channel type MOSFET transistors that relates to “normally on”, or “depletion mode”, type (see, e.g. the classification in P. Horowitz, W. Hill, “The Art of Electronics”, Cambridge University Press, 1989); which is used for example in a pull circuitry described in EP0380095. This type of transistors has been considered as outdated and at present is out of production at all.

Therefore, in the present application, when it is referred to n-channel MOSFET transistors, it is understood that n-channel enhancement MOSFET transistors are meant, while n-channel depletion mode MOSFET transistors are excluded from consideration.

According to another approach disclosed in U.S. Pat. No. 6,356,140, a pull up circuitry for an open-drain signal line comprises a circuitry for monitoring a slew rate of a signal on the open-drain signal line and a circuitry for providing a pull-up current to the open-drain signal line responsive to the monitored slew rate. This complicates the pull-up structure and increases its size significantly. Lastly, some of the prior art references mention same N-type enhancement MOSFET transistors which are employed in the present invention, but in connection with voltage mode logic only (see EP 0380095, U.S. Pat. No. 4,647,797 and U.S. Pat. No. 4,598,216).

However, the following problems arise when using this approach.

First of all, in the voltage mode logic voltage levels are determined by power supply rails and not sensitive to pull up strength.

In the current mode logic, the operating current is converted into signal voltage by means of pull ups. Since the operating current is nearly constant, to have the determined signal voltage levels, it is required to have accurate values of pull up strength.

Historically, p-transistors were used in pull up structures but for the same strength they have too much capacitance for high speed circuits. Therefore, resistors were used to substitute these p-transistors.

In this case, a new problem arises that technological variations of the pull up strength causes serious influence on the voltage applied to the next logic stage and significant deterioration of the logic operation.

Second, it shall be noted that in the prior art, switching processes are accelerated by varying the strength of the pull-up by applying control voltage derived from the signal itself. Inherently, this causes delay between signal changes and control signal applied to the pull up. This delay deteriorates the maximum frequency of a system operation.

In view of the foregoing it would, therefore, be desirable to improve data signaling speeds in communication systems employing an open-drain architecture without affecting the size of the employed pull-up structures whilst providing good response to current and voltage variations.

It is therefore a primary object of the present invention to provide a pull-up device with a predefined strength with low parasitic capacitance and good response to changes in current.

It is a further object of the present invention to improve the dynamic response of the pull up with respect to an ideal resistor.

### BRIEF SUMMARY OF THE INVENTION

The present invention relates to a pull-up structure with variable strength, which combines a resistor network with N type MOS transistors. This allows the pull up to be varied to compensate for process and temperature variations around a predefined pull-up strength, and at the same time provides low parasitic capacitance and a good dynamic response of the pull-up structure.

According to one example embodiment of the invention, a pull up structure comprises a N type MOSFET transistor with a resistor in parallel, wherein the transistor is supplied with a voltage from a voltage reference.

According to an improvement of the first example embodiment, a pull up structure comprises a N type MOSFET with a resistor placed across the source and drain of the MOSFET and another resistor placed between the source of the N Type MOSFET and the terminal of the pull up.

According to still another improvement of the first example embodiment, a pull up structure comprises a N type MOSFET with a resistor connected across the source and drain of the MOSFET and another resistor connected between the terminal of the pull up and a voltage supply higher than the voltage to which the drain of the MOSFET is connected, with the current split between the two power supplies.

According to another example embodiment, a pull up structure comprises a N type MOSFET transistor with a resistor in series with the gate.

Contrary to the conventional approach, according to the invention, the strength of the pull-up structure is maintained constant by using n-type MOSFET transistors with resistors, so that to produce a constant voltage at the output of the pull up structure, whatever changes occur in resistor's characteristics due to temperature and process variations.

Since these deviations are mainly caused by fluctuations in resistor's conductivity and resistance due to temperature and process variations, the inventive approach of the present invention is to compensate fluctuations in resistor's characteristics using transistors, in particular, n-type enhancement MOSFET's.

Furthermore, the n-type MOSFET transistor is supplied with a constant voltage from a voltage reference (see the description, p. 5, line 5, and FIGS. 3, 4, 5, 6). The combination of the above two features makes possible to solve the problem of the invention.

Further, a typical conventional cascade is configured of two FET elements, wherein p-type transistor is used to pull up the current and n-type transistor, for pulling down (such as in U.S. Pat. No. 5,250,854). The novel approach of the present invention is that the pull up circuit is made of n-type enhancement MOSFET transistors solely.

Thus, the inventive approach is to maintain constant the strength of the pull up and hence, the voltage amplitude, while using transistors to compensate fluctuations in conductivity and resistivity of resistors.

### BRIEF DESCRIPTION OF THE SEVERAL VIEWS OF THE DRAWINGS

For a better understanding of the present invention and the advantages thereof and to show how the same may be carried into effect, reference will now be made, by way of example, without loss of generality to the accompanying drawings in which:

FIG. 1 shows a typical prior art differential current mode circuit using pull up structures.

FIG. 2 shows prior art pull up structures using p-channel MOSFET (FIGS. 2a and 2b) and a further structure (FIG. 2c) using n-channel MOSFET.

FIG. 3 shows the very simplest embodiment according to the present invention.

FIG. 4 shows a second embodiment according to the present invention.

FIG. 5 shows a combination of the first and the second embodiments according to the present invention.

FIG. 6 shows a third embodiment illustrating an improved pull up structure according to the present invention with a resistor in series with the gate.

FIG. 7 shows an example circuit which is a combination of the first and second embodiments according to the invention.

FIG. 8 shows an example pull up circuit according to the third embodiment of the invention.

FIG. 9 shows an example pull up circuit according to the third embodiment of the invention, with transistors acting as resistors.

FIG. 10 shows a conventional replica bias circuitry which can be used to provide control voltages VT and VJ for the pull up circuits shown in FIGS. 8 and 9.

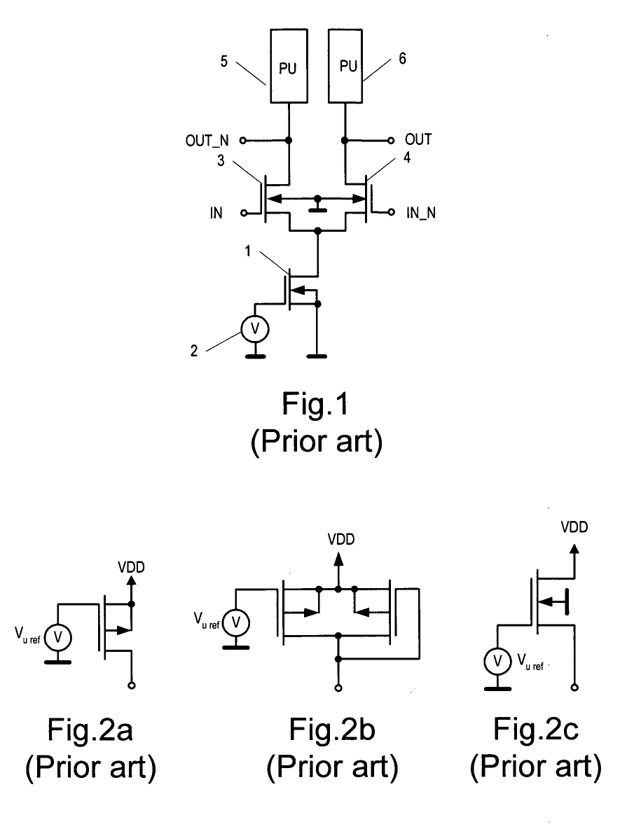

### DETAILED DESCRIPTION OF THE INVENTION

The invention will now be described in detail without limitation to the generality of the present invention with the aid of example embodiments and accompanying drawings. It shall be appreciated that same elements in the drawings are designated by similar reference signs.

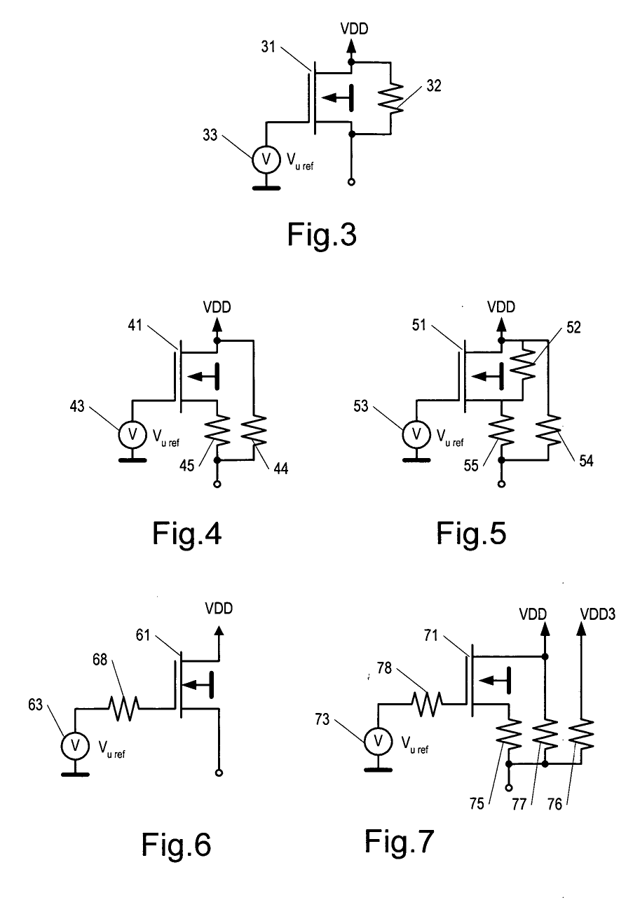

The present invention in its most basic form is an N-channel type MOS transistor 31, in parallel with a resistor 32, shown in FIG. 3. The total strength of the pull up is divided between the resistor and the transistor. The resistor value is chosen so that when the transistor is off or nearly off, while the process and temperature are such that cause the lowest resistance, the resistor provides the full strength of the pull up. When the transistor is supplied with the highest voltage from the voltage reference 33, the transistor in parallel with the resistor must provide the required drive strength. In this case, the size of the transistor will be minimised, while still being able to cover all variations of temperature and process. The combination of the transistor current and the resistor current can be calculated easily using basic network analysis. The second case is analysed for the corner where the combination of transistor and resistor has the maximum value of resistance with process and temperature variations.

It is not immediately obvious why an engineer would wish to adopt this basic circuit instead of one of the pull ups of FIG. 2a, 2b, 2c, however, the parasitic capacitance of the circuit shown in FIG. 3 is considerably lower than that of FIGS. 2 (a, b, c) due to the reduced size of the transistor. This translates into higher switching speeds for the differential circuits using the device.

The circuit in FIG. 4 adds to resistor 44 across the MOSFET to the pull up terminal, a second resistor 45, in series with the transistor 41. The purpose of this resistor 45 is to separate the capacitance of the transistor from the pull terminal. The size of this resistor can be determined using optimisation tools available within SPICE: when the resistor is too small too much of the transistor capacitance is seen by the terminal, and when it grows the transistor also grows to provide a lower resistance. The exact rate of growth depends on the precise process parameters, but given this simple objective of minimising the capacitance on the terminal, Avanti HSPICE optimisation tools can be used to determine the best values. If HSPICE is not available, any simulation tool can be used to simulate a ring oscillator built with stages having the pull ups, and then maximise the frequency of the ring oscillator as a function of the two variables of transistor width and resistor size.

A variation of this circuit within the scope of the present invention is to place the resistor 52 as shown in FIG. 5 across the drain to source of the N Type MOSFET 51, and for the second resistor 55 to connect the junction of the source of the N Type MOSFET and resistor 54 across the MOSFET to the pull up terminal.

In FIG. 6, still another example embodiment of the present invention is shown. The circuit in this figure represents a pull up structure comprising N type MOSFET transistor 61 with a resistor 68 in series with the gate.

In this improvement, resistor 68 is added, which dynamically modulates the strength of the pull-up during switching. The transistor itself has a gate capacitance. In combination with resistor 68, these form an equivalent RC network, which gives a delay when this time constant is close to the switching time that changes the current in the pull-up dynamically. When the voltage on the terminal of the pull-up goes from a high level to a low level, for a time ts, the strength of the pull-up is lower because the gate of the transistor is not charged to the final level.

This results in a faster transition down because the pull down circuitry will see a weaker pull up. When switching is finished, the strength of the pull-up will grow to the final value, when the gate is charged to the voltage reference level or a predefined product of the time constant and that voltage. Then, when the terminal is switched from low to high by the attached switching logic, such as the differential pull-down circuitry, then, for a time constant formed by the LC structure, the load is pulled up with high strength until the gate of the transistor 61 is discharged to a lower level. This uses the Miller capacitances, in this case from the source to gate rather than drain to gate, to change the voltage on the gate. The value of this resistor can be identified using the same ring oscillator frequency optimisation process that was described earlier.

The next improvement is to increase the voltage that can be dropped across the pull-up. This resistor is shown as resistor 76 in FIG. 7 illustrating another embodiment of the present invention. This improvement is useful where there is limited headroom for the transistor in series with the other transistors in the structure. This is an issue when differential current mode logic is used in processes with low Vdd, for example 1.2V Vdd. The differential circuit will have at least three transistors in series using the present invention and without this extra resistor, in very low voltage circuits such as are common in very small feature size processes, insufficient headroom for the transistors to operate. The value of the resistor 76 is calculated using two equations, with reference to FIG. 7, to achieve that resistors 76 and 77 in FIG. 7 in parallel have the same resistance as the original resistor 44 in FIG. 4.

When the transistor 71 is fully off, the voltage on the terminal of the pull-up must not exceed any of the breakdown voltage of the previous transistor or the transistor connected to the stage, particularly the gate oxide breakdown voltage.

The first equation takes the form of:

1/R₂=1/R₆+1/R₇,

and the second equation is:

R₇(V_{dd}3max−V_{dd}max)/(R₆+R₇)+V_{dd}<Vbreakdown,

where V_{dd}3max is the maximum level of V_{dd}3, V_{dd}max is the maximum level of V_{dd} and Vbreakdown is the lowest breakdown voltage.

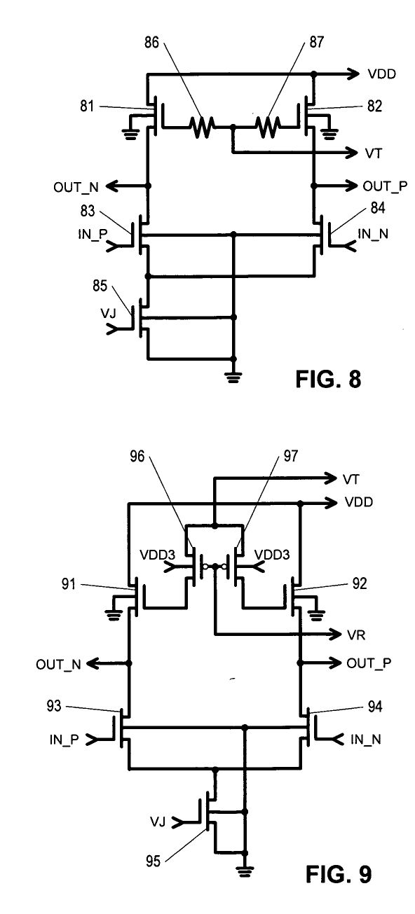

Example implementation circuits of the third embodiment of the invention are shown in FIGS. 8 and 9, where, a pull up structure in FIG. 8 is implemented using resistors in series with the gates, while a pull up circuit in FIG. 9 uses transistors as resistors.

In more detail, a circuit in FIG. 8 is a differential buffer stage comprising a pair of transistors 81 and 82 for controlling the amplitude of an output signal and a pair of transistors 83, 84 which operates as switch. To dynamically modulate the strength of the pull-up during switching, resistors 86, 87 are connected in series with gates of transistors 81, 82. The biased NMOS devices 81 and 82 are equally sized as required by circuitry symmetry, same as the pair of transistors 83 and 84.

The buffer stage further includes N-transistor current source 85 to which is applied a bias control voltage VJ. A load control voltage VT is supplied to gates of transistors 81 and 82 via resistors 86, 87.

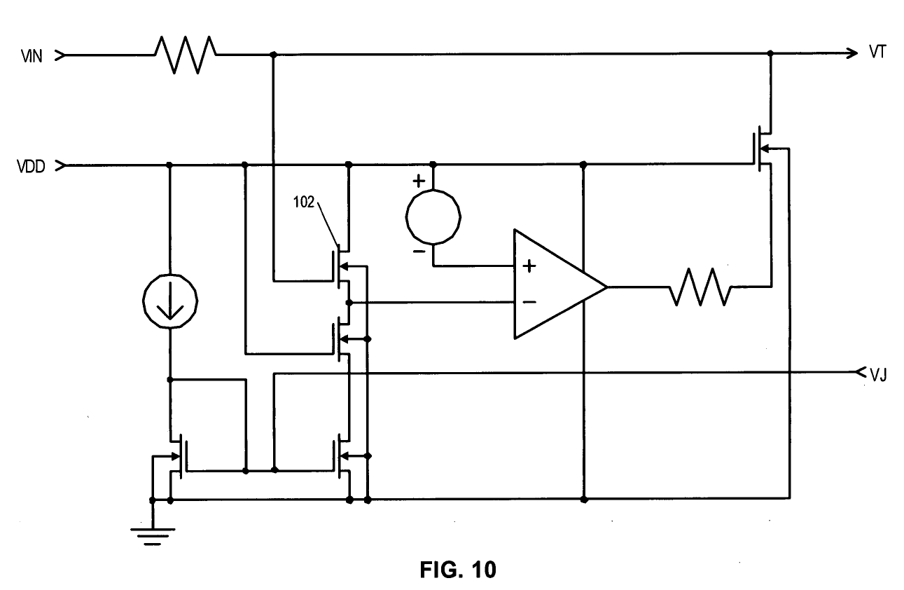

The differential buffer of FIG. 8 is configured to receive differential signals at input signal ports IN_P and IN_N and to provide differential buffer stage outputs at output ports OUT_P and OUT_N. The operating current and output voltage in the circuit is controlled by load voltage level VT and bias control voltage VJ generated by a replica bias circuitry shown in FIG. 10.

The replica bias circuitry of FIG. 10 is specifically adapted to provide the required voltage levels VJ and VT to control pull ups made of MOS transistors, in particular, to generate VT which exceeds a supply voltage Vdd.

In conventional circuitries, to provide operation of pull ups, such as pull up 102, it is required that VIN>>Vdd. This typically causes overvoltages of transistors. The above problem is solved by the replica bias circuitry shown in FIG. 10, which provides normal operation of a cascade of transistors, while no one voltage exceeds the admissible level. The VIN requires small currents while the voltage can be twice as high as Vdd.

Back to FIG. 8, the advantage of the differential amplifier according to the invention over the prior art is that the strength of the pull-up during switching can be dynamically modulated by using resistors 86, 87.

Each one of transistors 81, 82 itself has its gate capacitance which, in combination with resistors 86, 87, respectively, forms an equivalent RC network, which gives a delay when this time constant is close to the switching time that changes the current in the pull-up dynamically. When the voltage on the terminal of the pull-up goes from a high level to a low level, for a time ts, the strength of the pull-up is lower because the gate of the transistor is not charged to the final level.

As has already been described above, this results in a faster transition down because the pull down circuitry will see a weaker pull up. When switching is finished, the strength of the pull-up will grow to the final value, when the gate is charged to the voltage reference level or a predefined product of the time constant and that voltage. Then, when the terminal is switched from low to high by the attached switching logic 83, 84, such as the differential pull-down circuitry, then, for a time constant formed by LC structure, the load is pulled up with high strength until the gates of transistors 81, 82 are discharged to a lower level.

Respectively, the use of such buffers in voltage controlled oscillators provides changing the frequency of the oscillator by changing the voltage.

In FIG. 9, a similar buffer stage is shown, but with transistors 96, 97 acting in a same way as resistors 86, 87 in FIG. 8. Additional voltage VR controls the strength of transistors 96, 97.

This embodiment is especially advantageous to provide circuits of reduced size, or, when resistors cannot be used.

The additional advantage of the above described circuits is that by switching inputs/outputs, it can be easily converted from buffer stages into inverters, when required.

It shall be appreciated that the circuits shown here operate only with N Type MOSFETs, as the P Type Devices which are in the prior art for pull-ups operate with the opposite effect. One skilled in the art will appreciate that the present invention may be practiced by other than the described embodiments, which are presented for purposes of illustration and not of limitation, and that the present invention is limited only by the appended claims.

We claim:

1. A pull up structure comprising a N type MOSFET transistor (31) with a resistor (32) in parallel, wherein the transistor is supplied with a voltage from a voltage reference (33).

2. A pull up structure according to claim 1, wherein the resistor is connected across the source and drain of the MOSFET (31).

3. A pull up structure according to claim 1, wherein the resistor comprises two elements (45,44), connected in parallel with the N type MOSFET (41) with a tap to the terminal of the pull up between the two resistor elements.

4. A pull up structure according to claim 1, wherein an additional resistor (55) is placed between the source of the N Type MOSFET and the terminal of the pull up.

5. A pull up structure according to claim 1, further comprising a resistor (68) in series with the gate.

6. A pull up structure according to claim 5, wherein the resistor is selected such that the resistor in conjunction with the N-Type MOSFET gate capacitance has a time constant which minimises the switching time of the logic elements which the pull up serves.

7. A pull up structure according to claim 1, further comprising a resistor (66) connected between the terminal of the pull up and a voltage supply higher than the voltage to which the drain of the MOSFET is connected, with the current split between the two power supplies.

8. A pull up structure according to claim 1, wherein the resistor value is chosen so that when the MOSFET is off or nearly off, with the process and temperature which causes the lowest resistance, the resistor provides the full strength of the pull up.

9. A pull up structure according to claim 1, wherein an additional resistor is placed between the source of the N Type MOSFET and the terminal of the pull up.

10. A pull up structure comprising a N type MOSFET (51) with a resistor (52) placed across the source and drain of the MOSFET (51) and another resistor (55) placed between the source of the N Type MOSFET and the terminal of the pull up.

11. A pull up structure according to claim 10, wherein the transistor is supplied with a voltage from a voltage reference (53).

12. A pull up structure according to claim 10, wherein the resistor value is chosen so that when the MOSFET is off or nearly off, with the process and temperature which causes the lowest resistance, the resistor provides the full strength of the pull up.

13. A pull up structure according to claim 10, wherein the transistor is supplied with a voltage from a voltage reference

14. A pull up structure comprising a N type MOSFET (71) with a resistor connected across the source and drain of the MOSFET and another resistor (76) connected between the terminal of the pull up and a voltage supply higher than the voltage to which the drain of the MOSFET is connected, with the current split between the two power supplies.

15. A pull up structure according to claim 14, further comprising a resistor having two elements (75, 77) connected in parallel with the N type MOSFET with a tap to the terminal of the pull up between the two resistor elements.

16. A pull up structure according to claim 14, wherein an additional resistor (78) is placed between the source of the N Type MOSFET and the terminal of the pull up.

17. A pull up structure according to claim 14, wherein the resistor value is chosen so that when the MOSFET is off or nearly off, with the process and temperature which causes the lowest resistance, the resistor provides the full strength of the pull up.

18. A pull up structure according to claim 14, wherein the transistor is supplied with a voltage from a voltage reference.

19. A pull up structure comprising a N type MOSFET transistor (61) with a resistor (68) in series with the gate.

20. A pull up structure of claim 19, wherein the resistor is implemented as a transistor.
